(19) United States
(12) Patent Application Publication
(10) Pub. No.: US 2022/0208513 A1
(43) Pub. Date: Jun. 30, 2022

(54) SUBSTRATE TREATING APPARATUS

(71) Applicant: SEMES CO., LTD., Cheonan-si (KR)

(72) Inventors: OGSEN GALSTYAN, Cheonan-si (KR); HYUK JIN LEE, Seoul (KR); YOUNG-BIN KIM, Hwaseong-si (KR); YOUN GUN BONG, Suwon-si (KR); JONG-HWAN AN, Yongin-si (KR)

(73) Assignee: SEMES CO., LTD., Cheonan-si (KR)

(21) Appl. No.: 17/563,252

(22) Filed: Dec. 28, 2021

(30) Foreign Application Priority Data
Dec. 28, 2020 (KR) 10-2020-0184821

(51) Int. Cl. H01J 37/32

(52) U.S. Cl. CPC H01J 37/3211; H01J 37/32119; H01J 37/3244

(57) ABSTRACT

A substrate treating apparatus includes a chamber having a treating space therein, a substrate support unit supporting a substrate in the treating space, a gas supply unit supplying a gas into the treating space, and a plasma generation unit exciting the gas within the treating space to generate plasma. The plasma generation unit includes an RF power supplying an RF signal, and a first antenna and a second antenna being supplied with the RF signal to generate the plasma from the gas supplied inside the treating space. The first antenna is disposed at an inside of the second antenna. The coils included in the second antenna are stacked on each other at a second height, and coils included in the first antenna are stacked on each other at a first height, the second height being greater than the first height.

### CROSS-REFERENCE TO RELATED APPLICATIONS

A claim for priority under 35 U.S.C. § 119 is made to Korean Patent Application No. 10-2020-0184821 filed on Dec. 28, 2020, in the Korean Intellectual Property Office, the entire contents of which are hereby incorporated by reference.

### BACKGROUND

Embodiments of the inventive concept described herein relate to a substrate treating apparatus, more specifically, a substrate treating apparatus for etch treating a substrate using a plasma.

A process of manufacturing a semiconductor, a display, a solar cell, or the like includes a process of treating a substrate using a plasma. For example, an etching apparatus or an ashing apparatus used for ashing during a semiconductor manufacturing process may include a chamber for generating the plasma, and the substrate may be etched or ashing-treated using the plasma.

A plasma apparatus may be classified as a Capacitive Coupled Plasma (CCP) apparatus and an Inductively Coupled Plasma (ICP) apparatus according to an application method of an RF power. The Capacity Coupled Plasma apparatus generates the plasma using an RF electric field formed vertically between electrodes by applying the RF power to opposing electrodes. The Inductively Coupled Plasma apparatus converts a source material into the plasma using an induced electric field induced by an antenna.

The Inductively Coupled Plasma apparatus may distribute a current to a plasma antenna through a matcher and a current divider connected to the RF power, and control a coupling between an inner coil and an outer coil. In addition, through this, the current ratio between the inner coil and the outer coil may be controlled, and through this, a radial uniformity of plasma etching may be controlled. However, in the Inductively Coupled Plasma apparatus, there is still a problem in that an etching rate between the edge region of the chamber and the central region of the chamber is different.

### SUMMARY

Embodiments of the inventive concept provide an antenna structure capable of increasing a plasma density in an edge region of a chamber.

The problems to be solved by the inventive concept are not limited to the above-mentioned problems. Other technical problems not mentioned will be clearly understood by those skilled in the art to which the inventive concept pertains from the following description.

According to an embodiment of the present invention, a substrate treating apparatus includes: a chamber having a treating space therein; a substrate support unit supporting a substrate in the treating space; a gas supply unit supplying a gas into the treating space; and a plasma generation unit exciting the gas within the treating space to generate plasma. The plasma generation unit includes: a radio frequency (RF) power supplying an RF signal; and a first antenna and a second antenna being supplied with the RF signal to generate the plasma from the gas supplied inside the treating space. The first antenna is disposed at an inside of the second antenna. The first antenna includes a first coil having a first height. The second antenna includes a second coil having a second height greater than the first height.

According to an embodiment of the present invention, a substrate treating apparatus includes: a chamber having a treating space therein; a dielectric window sealing a tope of the chamber; a substrate support unit supporting a substrate at the treating space; a gas supply unit supplying a gas into the treating space; and a plasma generation unit exciting the gas within the treating space to generate plasma. The plasma generation unit includes: an RF power supplying an RF signal; and a first antenna and a second antenna being supplied with the RF signal to generate the plasma from the gas supplied inside the treating space. The first antenna is disposed at an inside of the second antenna. The second antenna includes a plurality of coils, and the plurality of coils included in the second antenna are on the dielectric window and are arranged such that a contact area of the second antenna with the dielectric window is minimized.

According to an embodiment of the present invention, a substrate treating apparatus includes: a chamber having a treating space therein; a substrate support unit supporting a substrate at the treating space; a gas supply unit supplying a gas into the treating space; and a plasma generation unit exciting the gas within the treating space to generate plasma. The plasma generation unit comprises: an RF power supplying an RF signal; and a first antenna and a second antenna being supplied with the RF signal to generate the plasma from the gas supplied inside the treating space. The first antenna is disposed at an inside of the second antenna. The second antenna includes a plurality of coils that are stacked on each other in a single stacked structure.

The effects of the inventive concept are not limited to the above-described effects. Effects not mentioned will be clearly understood by those skilled in the art to which this invention pertains from this specification and the accompanying drawings.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1A to FIG. 1C are views illustrating a substrate treating apparatus according to an embodiment of the inventive concept.

FIG. 2 is a perspective view illustrating in more detail a shape of an antenna according to an embodiment of the inventive concept.

FIG. 3 is a side view of a shape of the antenna according to an embodiment of the inventive concept.

FIG. 4A is a view illustrating a shape of an antenna, and FIG. 4B is a view illustrating a shape of the antenna according to an embodiment of the inventive concept.

FIG. 5A and FIG. 5B are views illustrating a substrate treating apparatus according to the inventive concept in a form of a circuit.

FIG. 6A and FIG. 6B are views illustrating a distribution of a magnetic field in a substrate treating apparatus and a substrate treating apparatus according to the inventive concept.

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

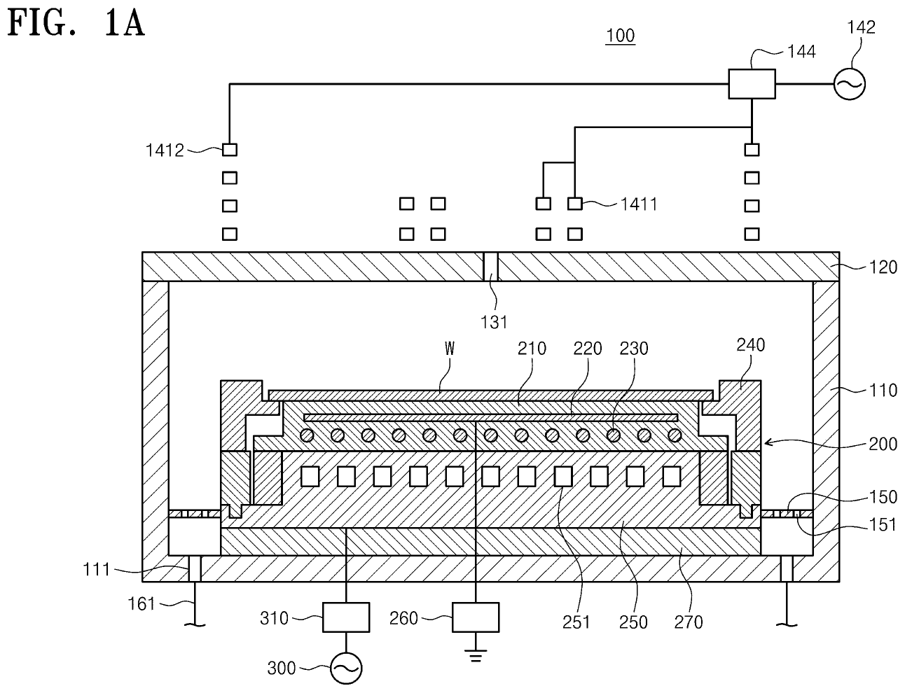

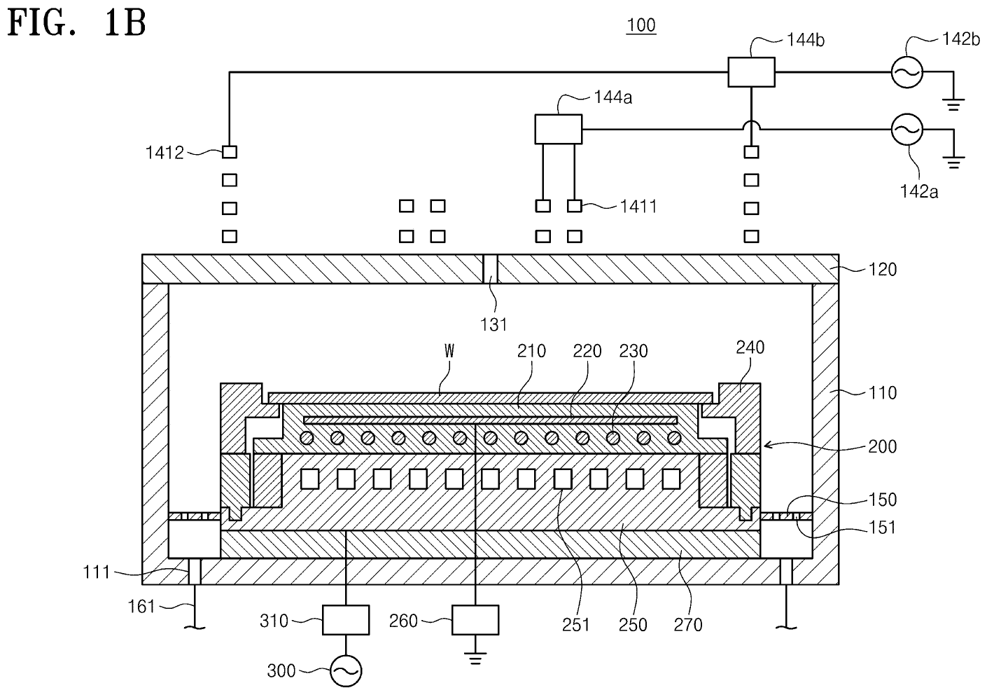

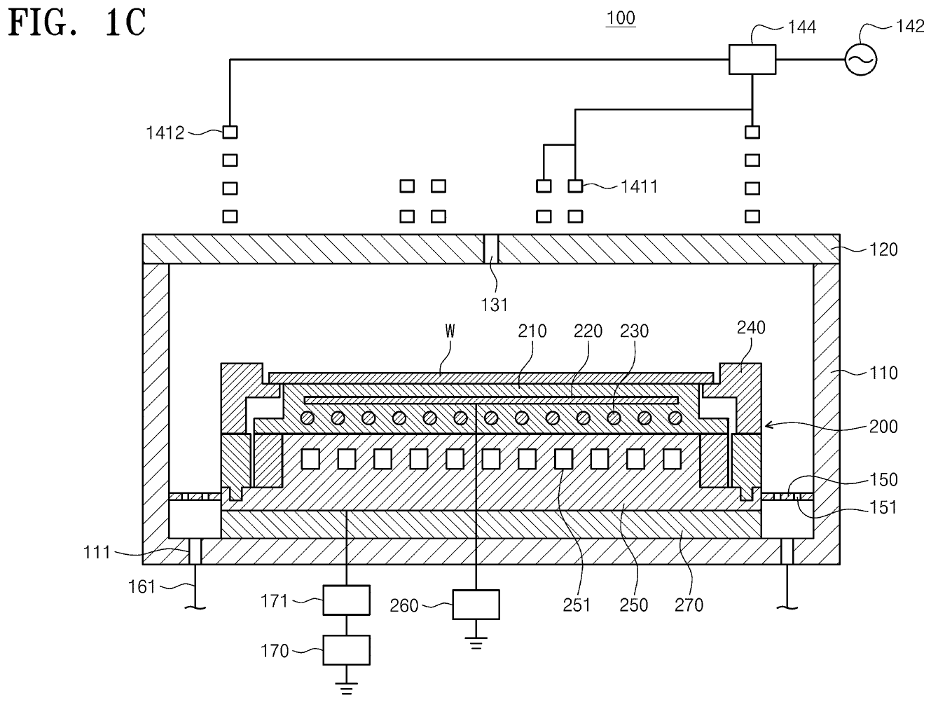

FIG. 1A to FIG. 1C are views illustrating a substrate treating apparatus according to an embodiment of the inventive concept.

Referring to FIG. 1A, the substrate treating apparatus 100 may include a body 110 (i.e., a process chamber), a dielectric window 120, a gas supply unit 130, a plasma generation unit 140, a baffle 150, and a substrate support unit 200.

A top surface of the body 110 is opened, and a space is formed therein. An inner space of the body 110 provides a space in which substrate treating is performed. An exhaust holes 111 may be formed at a bottom surface of the body 110. The exhaust holes 111 are connected to an exhaust line 161 and provide a passage through which reaction by-products generated during the process and gas remaining inside the body 110 are discharged to the outside. The dielectric window 120 seals the open top surface of the body 110. The dielectric window 120 has a radius corresponding to a circumference of the body 110. The dielectric window 120 may be formed of a dielectric material. The dielectric window 120 may be provided in an aluminum material. The chamber according to the inventive concept may be configured to include the body 110 and the dielectric window 120.

The gas supply unit 130 supplies a process gas onto the substrate W supported by the substrate support unit 200. The gas supply unit 130 includes a gas storage unit 135, a gas supply line 133, and a gas inlet port 131. The gas supply line 133 connects the gas storage unit 135 and the gas inlet port 131. The process gas stored in the gas storage unit 135 is supplied to the gas inlet port 131 through the gas supply line 133. The gas inlet port 131 is installed on a top wall of the chamber. The gas inlet port 131 is positioned to face the substrate support unit 200. According to an embodiment, the gas inlet port 131 may be installed at a center of the top wall of the chamber. A valve may be installed at the gas supply line 133 to open and close an inner passage thereof, or to adjust a flow rate of gas flowing through the inner passage thereof. For example, the process gas may be an etching gas.

The baffle 150 controls a flow of the process gas in the body 110. The baffle 150 is provided in a ring shape and is positioned between the body 110 and the substrate support unit 200. At the baffle 150, through-holes 151 are formed. The process gas staying in the body 110 passes through the through-holes 151 and flows into the exhaust hole 111. The flow of the process gas flowing into the exhaust hole 111 may be controlled according to a shape and an arrangement of the through-holes 151.

The substrate support unit 200 is positioned inside the body 110 and supports the substrate W. The substrate support unit 200 may be provided with an electrostatic chuck for supporting the substrate W using an electrostatic force. Alternatively, the substrate support unit 200 may support the substrate W in various ways such as mechanical clamping. Hereinafter, an electrostatic chuck will be described as an example.

The substrate support unit 200 (e.g., an electrostatic chuck) may include a first plate 210, an electrode 220, a heater 230, and a focus ring 240. The first plate 210 is provided in a disk shape, and a substrate W is placed on a top surface thereof. The top surface of the first plate 210 may be stepped so that a central region is higher than an edge region. The central region of the top surface of the first plate 210 may have a radius smaller than that of the substrate W. Therefore, an edge region of the substrate W is located outside the top central region of the first plate 210. The first plate 210 may be provided as a dielectric plate made of a dielectric material.

An electrode 220 is provided within the first plate 210. The electrode 220 is connected to an external power source 260, and power is applied from the power source. The electrode 220 forms an electrostatic force between the electrode 220 and the substrate W to adhere the substrate W onto the top surface of the first plate 210.

A heater 230 is provided inside the first plate 210. The heater 230 may be provided under the electrode 220. The heater 230 is electrically connected to an external power source 260 and generates a heat by resisting an applied current. The generated heat is transferred to the substrate W through the first plate 210. The substrate W is heated to a predetermined temperature by the heat generated by the heater 230. The heater 230 may be provided as a spiral shape coil. The heater 230 may be buried in the first plate 210 at uniform intervals.

A body disposed under the first plate 210 may include a metal plate. According to an embodiment, the entire body may be provided as a metal plate. The body may be electrically connected to an additional power source 300. The additional power source 300 may be provided as a high frequency power source generating a high frequency power. The high frequency power source may include an RF power. The body may receive the high frequency power from the additional power source 300. For this reason, the body can function as an electrode, that is, a bottom electrode. An additional matcher 310 may be disposed between the body and the additional power source 300 to perform an impedance matching.

A focus ring 240 is provided in a ring shape and is disposed along a circumference of the first plate 210. A top surface of the focus ring 240 may be provided by being stepped so that an inner portion adjacent to the first plate 210 is lower than an outer portion. The inner portion of the top surface of the focus ring 240 may be positioned at the same height as a central region of the top surface of the first plate 210. The inner portion of the top surface of the focus ring 240 supports the edge region of the substrate W positioned outside the first plate 210. The focus ring 240 expands an electric field forming region so that the substrate is positioned at a center of the region in which the plasma is formed.

The plasma generation unit 140 excites the process gas supplied into the chamber into a plasma state. The plasma generation unit 140 may include antennas 1411 and 1412, an RF power source 142, and a matcher 144 (i.e., an impedance matcher). The antennas 1411 and 1412 may be positioned above the dielectric window 120 and may be provided as a spiral shape coil. The RF power source 142 is connected to the antennas 1411 and 1412, and may apply a high frequency power to the antenna 141. The matcher 144 may be connected to an output terminal of the RF power source 142 to match an output impedance of the power source side with an input impedance of a load side. The matcher 144 may include a current distributor 143. The current distributor 143 may be integrated into the matcher 144 to be implemented. However, unlike this, the matcher 144 and the current distributor 143 may be provided as separate components and implemented. The current distributor 143 may distribute a current supplied from the RF power source 142 to the antennas 1411 and 1412. By the high frequency power applied to the antennas 1411 and 1412, an induced electric field is formed inside the chamber. The process gas is excited in a plasma state by obtaining an energy required for ionization from the induced electric field. The process gas in a plasma state is provided to the substrate W and treats the substrate W. The process gas in the plasma state may perform an etching process.

In FIG. 1, the antenna 141 included in the substrate treating apparatus 100 may include a first antenna 1411 and a second antenna 1412. In the ICP process chamber of FIG. 1, the plasma is formed by an azimuthal electric field through an induction coil separated from the chamber by the dielectric window 120.

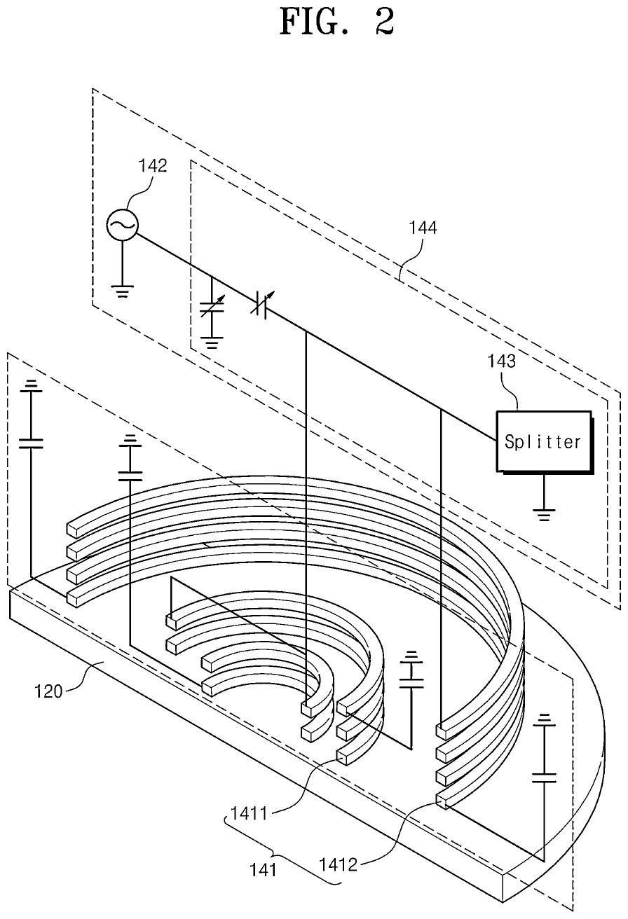

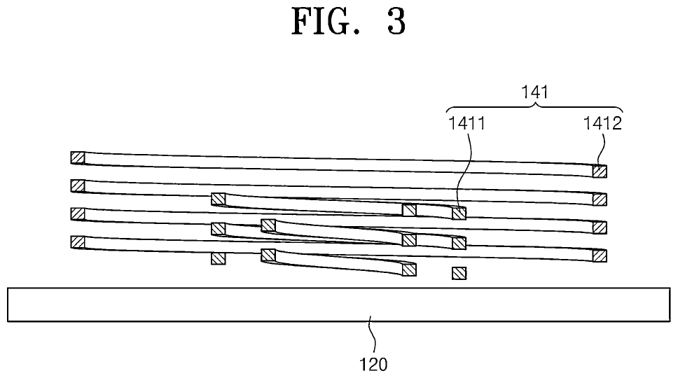

The first antenna 1411 and the second antenna 1412 may receive an RF signal to generate the plasma from the gas supplied into the treating space in the chamber. The first antenna 1411 may be disposed inside the second antenna 1412. The first antenna 1411 may be an internal antenna. The second antenna 1412 may be an external antenna. The first antenna 1411 and the second antenna 1412 may be connected in parallel. Each of the first antenna 1411 and the second antenna 1412 may include a coil. A detailed structure of the first antenna 1411 and the second antenna 1412 will be described later with reference to FIG. 2 to FIG. 3.

FIG. 1B is a view illustrating an example of a substrate treating apparatus according to an embodiment of the inventive concept.

A description of an overlapping part with FIG. 1B will be omitted. According to an embodiment of FIG. 1B, the RF power may be provided as a plurality of RF power sources 142a and 142b to be connected to the first antenna 1411 and the second antenna 1412, respectively. Accordingly, the first antenna 1411 and the second antenna 1412 may receive the high frequency power through a separate RF power. A first matcher 144a (i.e., a first impedance matcher) may match an impedance of the first RF power source 142a with a load side impedance. A second matcher 144b (i.e., a second impedance matcher) may match an impedance of the second RF power source 142b with the load side impedance. In an embodiment of FIG. 1B, the first matcher 144a and the second matcher 144b may not include the current distributor.

FIG. 1C is a view illustrating an example of a substrate treating apparatus according to an embodiment of the inventive concept.

Similarly, a description of the overlapping portion with FIG. 1A will be omitted. According to an embodiment of FIG. 1C, a lower power source may include a DWG 170 and a lower matcher 171.

According to an embodiment, the substrate treating apparatus according to the inventive concept may include a designed waveform generator (hereinafter may be referred to as a DWG or a set waveform generator) 170. The designed waveform generator 170 may generate an output voltage Volt having an arbitrary waveform (hereinafter referred to as a “set waveform”) set by an operator, and may provide a generated output voltage V out to the body 110. For example, the set waveform may be output at frequencies of several kHz to several MHz, and may be output at any variable voltage level of several tens of V to several tens of kV. A semiconductor wafer W on which a process is to be performed may be disposed in the body 110, and a semiconductor process may be performed on the semiconductor wafer W using an output voltage provided therein.

The set waveform generator 170 may include at least one pulse module generating a square wave and at least one slope module generating a variable waveform. At least one pulse module may be implemented with a plurality of pulse modules, and at least one slope module may be implemented with a plurality of slope modules. The number of pulse modules and the number of slope modules may be variously selected according to embodiments.

A maximum output voltage of the set waveform generator 170 may be determined according to the number of pulse modules and the number of slope modules. The output voltage of the set waveform generator 170 may correspond to a sum of a DC voltage supplied to at least one pulse module and a DC voltage supplied to at least one slope module. Specifically, at least one pulse module and at least one slope module may be connected to each other, and thus the set waveform generator 170 may provide a voltage level corresponding to the sum of the DC voltage supplied to at least one pulse module and the DC voltage supplied to at least one slope module.

The plurality of pulse modules may include at least one positive pulse module that generates a positive voltage and/or at least one negative pulse module that generates a negative voltage. A plurality of slope modules may include at least one positive slope module that generates a positive voltage and/or at least one negative slope module that generates a negative voltage.

In the embodiment, at least one pulse module and at least one slope module may be connected in a cascade manner. Here, when a plurality of modules are connected, the cascade method represents a method of connecting the output of one module in series with an input of another module, and may be referred to as a cascade connection. In an embodiment, the output of at least one pulse module may be connected to an input of at least one slope module. However, the inventive concept is not limited thereto, and the output of at least one slope module may be connected to an input of at least one pulse module.

Hereinafter, a structure of the antenna 141 according to the inventive concept will be described with reference to more detailed drawings.

FIG. 2 is a perspective view illustrating a structure of the antenna 141 according to an embodiment of the inventive concept in more detail.

Referring to FIG. 2, in the inventive concept, in order to reduce a mutual coupling between coils and increase a magnetic field in an edge region of a plasma chamber, a plurality of coils vertically stacked with the second antenna 1412 disposed at the edge region may be used. The second antenna 1412 may include a plurality of coils. According to an embodiment, the second antenna 1412 has a coil shape that is wound a plurality of times in an up/down direction. Hereinafter, an area rotated once in the antenna 1412 is referred to as one coil. According to an example, the second antenna 1412 has a plurality of coils, and the coils have a same diameter and are provided to overlap each other when viewed from above.

In order to increase a density of the plasma in an outer region, that is, an edge region of the etching chamber, it is important to reduce a capacitive coupling of an ICP coil through a dielectric window. To this end, in the inventive concept, the second antenna 1412 included in an ICP source is applied in a structure in which the coils are stacked. Accordingly, there is an effect of reducing the capacitive coupling of the second antenna 1412 coil to the dielectric window. In addition, the coupling between the first antenna 1411 coil and the second antenna 1412 coil may be reduced to improve a current ratio control of the first antenna 1411 to the second antenna 1412.

In the case of the antenna according to an embodiment of the inventive concept, an antenna structure including a double-stacked first antenna 1411 and a single-stacked second antenna 1412 may be disclosed. Among them, the first antenna 1411 refers to a structure in which two coils having different diameters are provided and coils having a same diameter are stacked on each other. The single stacked second antenna 1412 includes only coils having the same diameter, and refers to a structure in which they are stacked on each other. Through such a design structure, there is an effect of increasing an inductive coupling of the second antenna 1412 to the plasma in the edge region.

FIG. 3 is a side view of a shape of the antenna 141 according to an embodiment of the inventive concept.

According to an embodiment of FIG. 3, a total height of the second antenna 1412 may be provided to be higher than a total height of the first antenna 1411. According to an embodiment, a total height formed by the coils included in the second antenna 1412 may be provided to be higher than a total height formed by the coils included in the first antenna 1411. According to an embodiment, the number of coils included in the second antenna 1412 may be greater than the number of coils included in the first antenna 1411.

According to an embodiment, the first antenna 1411 may be provided by twisting two coils. According to an embodiment, the second antenna 1412 may be provided by stacking four coils sequentially.

The inventive concept may adopt an antenna structure for increasing the number of winding in an axial direction in order to overcome a problem of having difficulty in increasing the number of winding in a horizontal direction of the coil due to space constraints.

According to an embodiment, all coils included in the second antenna 1412 may be provided at positions overlapping when viewed from above. Accordingly, it may be confirmed that the second antenna 1412 is stacked as a single layer even though a plurality of coils are included. In addition, through this, the plurality of coils included in the second antenna 1412 may be provided in a structure capable of minimizing a contact area between the second antenna 1412 and the dielectric window.

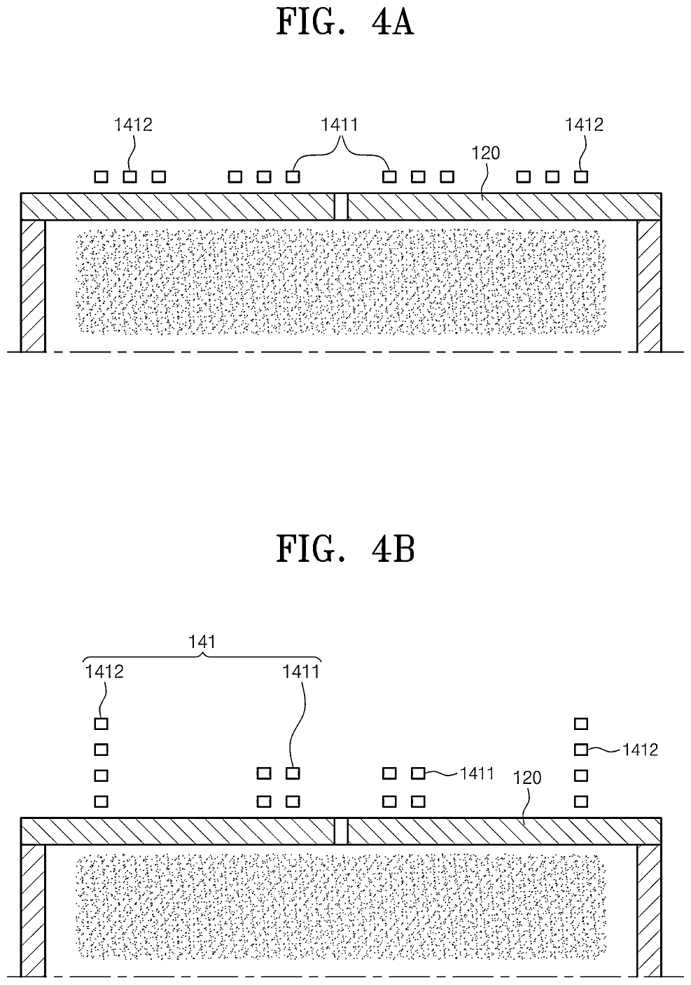

FIG. 4A is a view illustrating a shape of an antenna, and FIG. 4B is a view illustrating a shape of the antenna according to an embodiment of the inventive concept.

In the case of FIG. 4A, an embodiment provided as a coil extending on the same plane as in the shape of an antenna is disclosed. Referring to FIG. 4A, since a distance between the first antenna 1411 and the second antenna 1412 is close, there is a problem in that mutual coupling between a coil included in the first antenna 1411 and a coil included in the second antenna 1412 is high. In addition, there is a problem in that a flat coil as shown in FIG. 4A has a large surface area in contact with the dielectric window 120, and thus capacitive coupling through a plasma Cd through the dielectric window appears greatly.

To overcome this, when the second antenna 1412 is disposed farther from the first antenna 1411, a distance between the inner wall of the chamber and the coil included in the second antenna 1412 becomes close, resulting in a large amount of the magnetic field escaping to the outside.

FIG. 4B illustrates a shape of the antenna according to an embodiment of the inventive concept. When the antenna is formed as in an embodiment of the inventive concept, a distance between a coil included in the first antenna 1411 and a coil included in the second antenna 1412 may increase to reduce mutual coupling.

Referring to FIG. 4B, it may be confirmed that the antenna structure according to the inventive concept has a smaller area in which the second antenna 1412 contacts the dielectric window 120 compared to the antenna structure of FIG. 4A.

As the contact surface of the antenna increases, there is a problem in that a capacity coupling through the dielectric window 120 increases. The vertical stacked structure of the coils included in the second antenna 1412 according to the inventive concept has an effect of minimizing the contact surface of the coil contacting the dielectric window 120, thereby reducing the capacitive coupling through the dielectric window 120 and directing the magnetic field to the outermost region of the plasma chamber. In addition, since the contact area with the dielectric window 120 is small, there is an effect of minimizing the influence of by-products or particles generated. Through this structure, a maximum effect at an extreme edge portion of the etching chamber may be obtained.

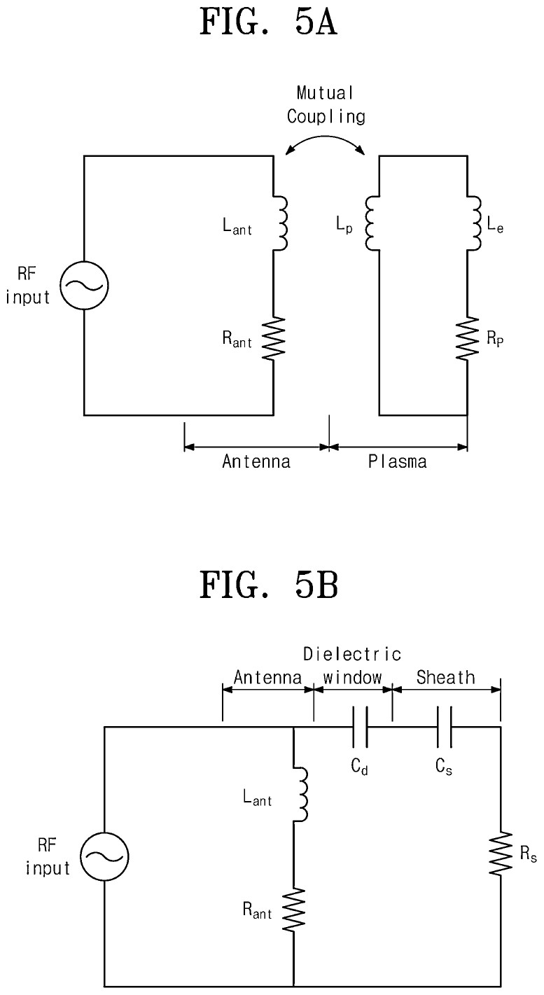

FIG. 5A to FIG. 5B are views illustrating a substrate treating apparatus according to the inventive concept in the form of a circuit.

FIG. 5A illustrates the inductive coupling of a substrate treating apparatus according to the inventive concept.

The meaning of each symbol shown in FIG. 5A is as follows. Lₐₙₜ is an Antenna inductance, Rₐₙₜ is an Antenna resistance, Lₚ is a Plasma geometrical region coupled to a coil (donut shape), Lₑ is an Electron inertia inductance, and Rₚ is a Plasma Resistance.

Referring to FIG. 5A, since the mutual coupling between the inductance of the antennas and the inductance of the plasma occurs, more coils included in the second antenna 1412 may be formed to increase the inductive coupling.

FIG. 5B is a circuit view illustrating a capacitive coupling of a substrate treating apparatus according to the inventive concept.

The meaning of each symbol illustrated in FIG. 5B is as follows.

Lₐₙₜ represents an Antenna inductance, Rₐₙₜ represents an Antenna resistance, Ca_{d} represents a dielectric window capacitance, Cₛ represents a plasma sheath capacitance, and Rₛ represents a plasma sheath resistance.

According to FIG. 5B, the second antenna 1412 coil may be stacked as a single layer to reduce the capacitive coupling between the dielectric window and the capacitor in the plasma sheath.

According to the inventive concept, the plasma treatment may be more efficiently performed by reducing the capacitive coupling and increasing the inductive coupling. In addition, a high magnetic field can be secured by controlling them to have a high inductance.

In the inventive concept, in order to increase the plasma density in the edge region, the inductive power coupling may be increased, and the capacitive power coupling may be reduced.

According to an embodiment, by increasing the number of coils included in the second antenna 1412 to form a plurality of windings, there is an effect of securing a high magnetic field at the edge portion of the chamber.

That is, according to the inventive concept, there is an effect of reducing the capacitive coupling by reducing a contact area with a dielectric window through a stack structure of coils included in the second antenna 1412, and increasing the inductance through the structure including a plurality of windings in the second antenna 1412. In addition, through this, there is an effect of satisfying the uniformity of plasma density by concentrating the magnetic field on the edge.

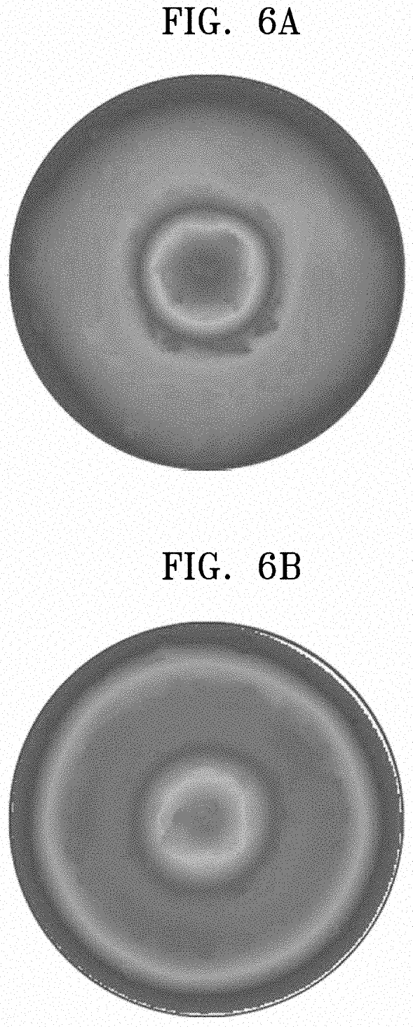

FIG. 6A is illustrating a distribution of a magnetic field in a conventional substrate treating apparatus. FIG. 6B is illustrating a distribution of a magnetic field in a substrate treating apparatus and a substrate treating apparatus according to the inventive concept.

FIG. 6A shows results of measured using an axial magnetic field measured below the dielectric window and a magnetic PCB coil sensor when a value of CR is 1 in the conventional substrate treating apparatus, and FIG. 6B shows results measured using the magnetic PCB coil sensor when a value of CR is 1 below the dielectric window according to the inventive concept. In FIG. 6A, the term CR means a ratio of an inner current flowing an inner antenna to an outer current flowing an outer antenna surrounding the the first antenna. In FIG. 6B, the term CR means a ratio of an inner current flowing a first antenna 1411 to an outer current flowing a second antenna 1412.

When the substrate treating apparatus according to the inventive concept is used, a result of increasing the magnetic field under the coil of the second antenna 1412 may be confirmed. Through this, it can be confirmed that the plasma density at the edge portion will also become uniform.

The effects of the inventive concept are not limited to the above-mentioned effects, and the unmentioned effects can be clearly understood by those skilled in the art to which the inventive concept pertains from the specification and the accompanying drawings.

Although the embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a chamber having a treating space therein;
a substrate support unit configured to support a substrate in the treating space;
a gas supply unit configured to supply a gas into the treating space; and
a plasma generation unit configured to excite the gas within the treating space to generate plasma,
wherein the plasma generation unit comprises:
a radio frequency (RF) power supplying an RF signal; and
a first antenna and a second antenna being supplied with the RF signal and configured to generate the plasma from the gas supplied inside the treating space,
wherein the first antenna is disposed at an inside of the second antenna,
wherein the first antenna includes a first coil having a first height, and
wherein the second antenna includes a second coil having a second height greater than the first height.

2. The substrate treating apparatus of claim 1,
wherein the second coil of the second antenna includes a plurality of coils in a single stacked structure.

3. The substrate treating apparatus of claim 1,
wherein the second coil of the second antenna includes a plurality of coils, and
wherein the plurality of coils of the second antenna have the same diameter as each other, and are stacked on each other.

4. The substrate treating apparatus of claim 2,
wherein the second coil of the second antenna includes a plurality of coils in a double stacked structure.

5. The substrate treating apparatus of claim 4,
wherein the first antenna and the second antenna are connected in parallel with each other.

6. The substrate treating apparatus of claim 5,
wherein a number of the plurality of coils of the second antenna is four.

7. The substrate treating apparatus of claim 6,
wherein a number of the plurality of coils in the first antenna is four or less.

8. A substrate treating apparatus comprising:
a chamber having a treating space therein;
a dielectric window configured to seal a top of the chamber;
a substrate support unit configured to support a substrate in the treating space;
a gas supply unit configured to supply a gas into the treating space; and
a plasma generation unit configured to excite the gas within the treating space to generate plasma,
wherein the plasma generation unit comprises:
an RF power supplying an RF signal; and
a first antenna and a second antenna being supplied with the RF signal and configured to generate the plasma from the gas supplied inside the treating space,
wherein the first antenna is disposed at an inside of the second antenna,
wherein the second antenna includes a plurality of coils, and
wherein the plurality of coils included in the second antenna are on the dielectric window and are arranged such that a contact area of the second antenna with the dielectric window is minimized.

9. The substrate treating apparatus of claim 8,
wherein the plurality of coils of the second antenna is arranged in a single stacked structure.

10. The substrate treating apparatus of claim 8,
wherein the plurality of coils of the second antenna have the same diameter as each other, and are stacked on each other.

11. The substrate treating apparatus of claim 9,
wherein the second antenna includes a plurality of coils that are stacked on each other in a double stacked structure.

12. The substrate treating apparatus of claim 11,
wherein the coils included in the second antenna have a total height which is higher than a total height of the coils included in the first antenna.

13. The substrate treating apparatus of claim 12,
wherein a number of the plurality of coils included in the second antenna is 4.

14. The substrate treating apparatus of claim 13,
wherein a number of the plurality of coils included in the first antenna is 4 or less.

15. A substrate treating apparatus comprising:
a chamber having a treating space therein;
a substrate support unit configured to support a substrate at the treating space;
a gas supply unit configured to supply a gas into the treating space; and
a plasma generation unit configured to excite the gas within the treating space to generate a plasma,
wherein the plasma generation unit comprises:
an RF power configured to supply an RF signal; and
a first antenna and a second antenna being supplied with the RF signal and configured to generate the plasma from the gas supplied inside the treating space, and
wherein the first antenna is disposed at an inside of the second antenna,
wherein the second antenna includes a plurality of coils that are stacked on each other in a single stacked structure.

16. The substrate treating apparatus of claim 15,
wherein the plurality of coils included in the first antenna are stacked on each other in a double stacked structure.

17. The substrate treating apparatus of claim 16,
wherein a total height of the coils of the second antenna is provided higher than a total height of the coils of the first antenna.

18. The substrate treating apparatus of any one of claim 15,
wherein a number of the plurality of coils included in the second antenna is 4.

19. The substrate treating apparatus of claim 18,
wherein a number of the plurality of coils included in the first antenna is 4 or less.

20. The substrate treating apparatus of claim 19,
wherein the first antenna and the second antenna are connected in parallel with each other.
